(19) United States
(12) Patent Application Publication
(10) Pub. No.: US 2020/0042025 A1
(43) Pub. Date: Feb. 6, 2020

(54) POWER SUPPLY CIRCUIT

(71) Applicant: FUJITSU LIMITED, Kawasaki-shi (JP)

(72) Inventor: Fujio Kurokawa, Nagasaki (JP)

(73) Assignee: FUJITSU LIMITED, Kawasaki-shi (JP)

(21) Appl. No.: 16/507,116

(22) Filed: Jul. 10, 2019

(30) Foreign Application Priority Data
Aug. 2, 2018 (JP) 2018-146186

(51) Int. Cl. G05F 1/46; H02M 3/156; G01R 27/26

(52) U.S. Cl. CPC G05F 1/46; G01R 27/26; H02M 3/156

(57) ABSTRACT

A power supply circuit includes a converter configured to convert an input voltage into an output voltage, a memory, and a processor coupled to the memory and the processor configured to control the converter so as to make the output voltage constant, control the converter so as to cause the output voltage to transit to a transient state, based on an instruction, measure a first time until the output voltage reaches a first voltage, based on the instruction, and generate a warning signal when the first time reaches a second time.

### CROSS-REFERENCE TO RELATED APPLICATION

This application is based upon and claims the benefit of the prior Japanese Patent Application No. 2018-146186 filed on Aug. 2, 2018, the entire contents of which are incorporated herein by reference.

### FIELD

The embodiments discussed herein are related to a power supply circuit.

### BACKGROUND

Techniques that detect deterioration of a converter (conversion unit) are known in the related art.

Related techniques are disclosed in, for example, Japanese Laid-open Patent Publication Nos. 2007-178337 and 2011-097680.

### SUMMARY

According to an aspect of the embodiments, a power supply circuit includes a converter configured to convert an input voltage into an output voltage, a memory, and a processor coupled to the memory and the processor configured to control the converter so as to make the output voltage constant, control the converter so as to cause the output voltage to transit to a transient state, based on an instruction, measure a first time until the output voltage reaches a first voltage, based on the instruction, and generate a warning signal when the first time reaches a second time.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a view illustrating an example of the configuration of a power supply circuit;

FIG. 2 is a view illustrating an example of the configuration of a voltage conversion unit;

FIG. 3 is a view illustrating an example of an output voltage fluctuation in a transient state;

FIG. 4 is a view illustrating an example of the configuration of the power supply circuit in more detail;

FIG. 5 is a view illustrating an example of the configuration of a microcomputer;

FIG. 6 is a view illustrating a first example of a data table;

FIG. 7 is a view illustrating a second example of the data table;

FIG. 8 is a view illustrating another example of the configuration of the voltage conversion unit;

FIG. 9 is a view illustrating first and second examples of an aged deterioration detection method;

FIG. 10 is a view illustrating an example of an output voltage waveform when a command value is changed in a state without deterioration;

FIG. 11 is a view illustrating an example of an output voltage waveform when the command value is changed in a state where a capacity is reduced by 10%;

FIG. 12 is a view illustrating an example of an output voltage waveform when the command value is changed in a state where the capacity is reduced by 20%;

FIG. 13 is a view illustrating another example of the configuration of the power supply circuit;

FIG. 14 is a view illustrating an example of a waveform of an output voltage V1 when a command value of an output voltage V2 is changed in a state without deterioration;

FIG. 15 is a view illustrating an example of a waveform of an output voltage V1 when a command value of an output voltage V2 is changed in a state where the capacity is reduced by 20% on the command value changing side;

FIG. 16 is a view illustrating an example of a waveform of an output voltage V1 when a command value of an output voltage V2 is changed in a state where the capacity is reduced by 20% on the command value fixing side;

FIG. 17 is a view illustrating an example of a waveform of an output voltage V1 when a command value of an output voltage V2 is changed in a state where the capacity is reduced by 20% on the command value changing side and the command value fixing side;

FIG. 18 is a view illustrating an example of a waveform of an output current when a command value of an output voltage V2 is changed in a state without deterioration;

FIG. 19 is a view illustrating an example of a waveform of an output current when a command value of an output voltage V2 is changed in a state where the capacity is reduced by 20% on the command value changing side,

FIG. 20 is a view illustrating an example of a waveform of an output current when a command value of an output voltage V2 is changed in a state where the capacity is reduced by 20% on the command value fixing side; and

FIG. 21 is a view illustrating an example of a waveform of an output current when a command value of an output voltage V2 is changed in a state where the capacity is reduced by 20% on the command value changing side and the command value fixing side.

### DESCRIPTION OF EMBODIMENTS

In the related art, since the deterioration of a conversion unit is determined based on the state of an output voltage output from the conversion unit immediately after the power is turned ON, the deterioration caused by aging of the conversion unit may not be detected unless the conversion unit in operation is temporarily stopped.

Hereinafter, an embodiment of a technique capable of detecting an aging of a conversion unit while the conversion unit is in operation will be described with reference to the accompanying drawings.

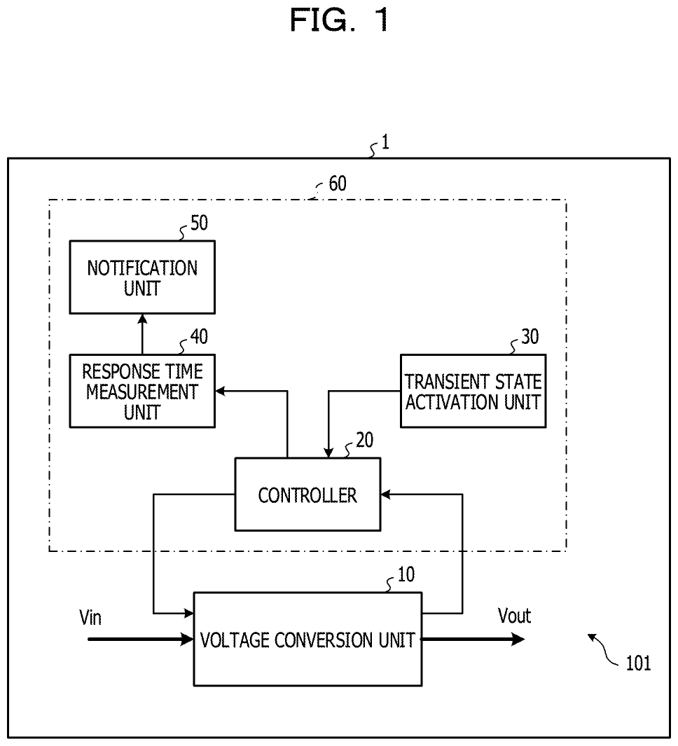

FIG. 1 is a view illustrating an example of the configuration of a power supply circuit according to an embodiment of the present disclosure. A power supply circuit 101 illustrated in FIG. 1 supplies a constant output voltage Vout to at least one load included in a device 1. The power supply circuit 101 may be built in the device 1 or externally attached. Specific examples of the device 1 may include an information and communication technology (ICT) device, an in-vehicle device, and the like. As more specific examples, the device 1 may include a communication base station, a server, a motherboard, a personal computer, a portable terminal device, and the like, but the specific examples of the device 1 are not limited to these devices.

The power supply circuit 101 is a switching power supply that generates a DC output voltage Vout from a DC input voltage Vin by switching at least one switching element in a voltage conversion unit 10 (hereinafter, also simply referred to as a “converter”).

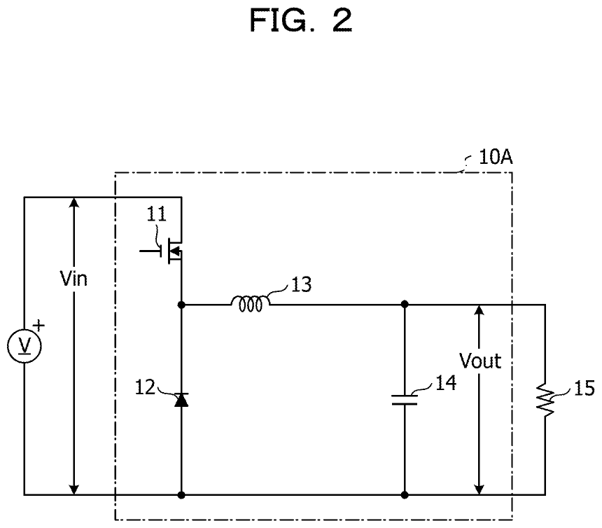

FIG. 2 is a view illustrating an example of the configuration of the voltage conversion unit 10. A back converter 10A is an example of the converter 10 and is a non-insulated DC-DC converter that steps down the input voltage Vin into the output voltage Vout. The term “DC” stands for Direct Current. An equivalent circuit of a general switching power supply circuit may be represented by a back converter.

The back converter 10A includes a switching element 11, a diode 12, an inductor 13, and an output capacitor 14. The input voltage Vin is input to one end of the switching element 11, and the other end of the switching element 11 is connected to the anode of the diode 12. A connection point between the other end of the switching element 11 and the anode of the diode 12 is connected to one end of the inductor 13, and the other end of the inductor 13 is connected to one end of the output capacitor 14. The cathode of the diode 12 and the other end of the output capacitor 14 are connected to the ground.

The back converter 10A performs a step-down conversion of the DC input voltage Vin input to the back converter 10A into the DC output voltage Vout by switching of the switching element 11, and supplies the DC output voltage Vout to a load 15. Specific examples of the switching element 11 may include bipolar transistors, field effect transistors, and the like. The output voltage Vout is smoothed by the output capacitor 14. A specific example of the output capacitor 14 may include an electrolytic capacitor.

However, when the back converter 10A (particularly, the output capacitor 14) is aging, the capacitance of the output capacitor 14 decreases. The decrease of the capacitance of the output capacitor 14 changes the time constant of the circuit of the back converter 10A. Therefore, a difference appears in the waveform in the transient state of the output voltage Vout before and after the aging of the back converter 10A.

Focusing on this difference, the power supply circuit 101 according to the present embodiment intentionally creates the transient state of the output voltage Vout while the back converter 10A is in operation, and measures the waveform in the transient state of the output voltage Vout so as to detect the aging of the converter 10A. Thus, even when the back converter 10A is temporarily stopped and the capacitance of the output capacitor 14 is not measured, the aging of the back converter 10A (particularly, the output capacitor 14) may be detected while the back converter 10A is in operation.

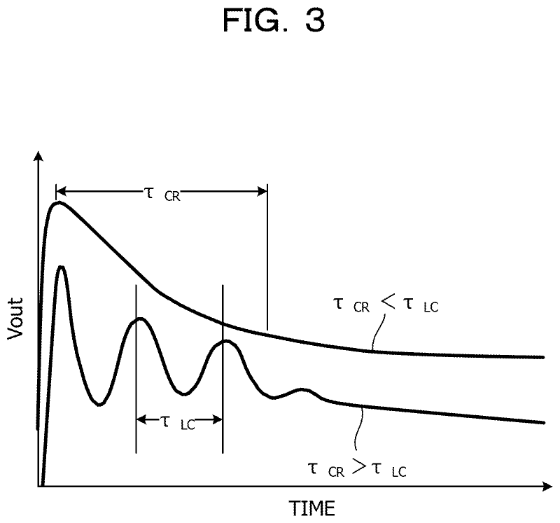

FIG. 3 is a view illustrating an example of an output voltage fluctuation in a transient state. The voltage fluctuation in the transient state may be explained with the magnitude relationship between a CR time constant τ_{CR} and an LC resonance period τ_{LC}. When the constant of a compensator is selected (set) to an appropriate value and the feedback system of the power supply circuit is stably controlled, the following expressions are obtained using a resistance R of the entire system, a capacitance C of the output capacitor 14, and an inductance L of the inductor 13.

τ_{CR}=C×R

τ_{LC}=2π×√(L×C)

Since the power consumption in a high efficiency power supply circuit occurs almost only at the load 15, the resistance R of the entire system is approximately equal to the resistance of the load 15.

When τ_{CR} is smaller than τ_{LC}, the output voltage Vout monotonously converges. In the meantime, when τ_{CR} is larger than τ_{LC}, the output voltage Vout at the time of transient response has an oscillating waveform of the period τ_{LC} whose envelope is τ_{CR}. Therefore, when the constants of the power supply circuit and the compensator are selected so that the relationship of “τ_{CR}>τ_{LC}” in which the output voltage Vout in the transient state becomes an oscillation waveform is satisfied at the time of creating (designing) the power supply circuit 101, a change in C may be detected as a change in τ_{LC}. That is, since the inductance L does not substantially change, it is possible to detect the change in the capacitance C (i.e., the aging of the output capacitor 14), for example, by measuring τ_{LC}.

For example, as the capacitance C decreases due to the aging of the output capacitor 14, τ_{LC} becomes smaller than a value before deterioration. Therefore, when it is detected that a measured value of τ_{LC} is smaller than a predetermined reference value, it may be determined that the output capacitor 14 is aging.

As illustrated in FIG. 1, the power supply circuit 101 according to the present embodiment includes a converter 10, a controller 20, a transient state activation unit (hereinafter, also simply referred to as an “activation unit”) 30, a response time measurement unit (hereinafter, also simply referred to as a “measurement unit”) 40, and a notification unit 50.

The converter 10 is a circuit that converts the input voltage Vin into a desired output voltage Vout. The controller 20 controls the converter 10 so that the output voltage Vout becomes constant with respect to the fluctuation of a load current consumed by a load to which the output voltage Vout is applied.

The activation unit 30 notifies the controller 20 of an instruction to cause the output voltage Vout to transit to a transient state (e.g., an instruction to change a set value (target value) of the output voltage Vout by a predetermined voltage change amount ΔV). The measurement unit 40 measures a time Ts until the output voltage Vout reaches a predetermined threshold voltage Vt, based on the instruction from the activation unit 30.

The notification unit 50 issues a warning when the time Ts measured by the measurement unit 40 reaches a predetermined threshold Tt. For example, the notification unit 50 notifies an alarm device outside the power supply circuit 101 of warning information indicating that the value of the time Ts or the time Ts is out of a predetermined range. The alarm device warns a user based on such warning information. The user may replace the converter 10 or the power supply circuit 101 before the converter 10 breaks down, based on the warning from the alarm device. It is also possible to replace the device 1 itself.

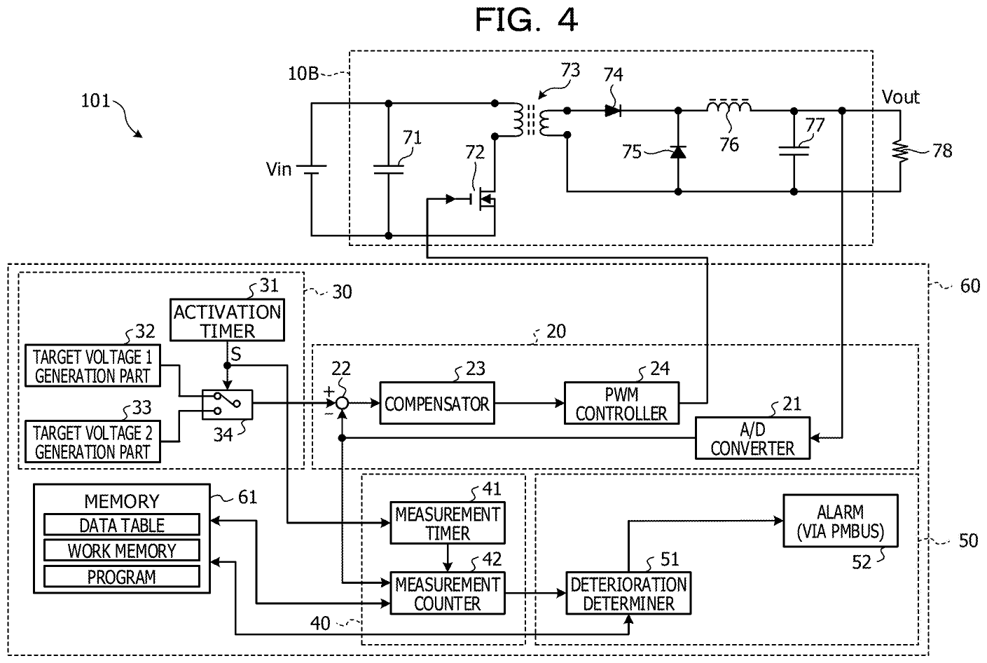

FIG. 4 is a view illustrating in more detail an example of the configuration of the power supply circuit according to the present embodiment. The power supply circuit 101 illustrated in FIG. 4 includes a converter 10B and a microcomputer 60.

The converter 10B is an example of the converter 10. The converter 10B is a forward converter that includes an input capacitor 71, a switching element 72, a transformer 73, diodes 74 and 75, a reactor 76, and an output capacitor 77. The converter 10B converts an input voltage Vin which is input from the outside of the converter 10B to the primary side of the transformer 73 into an output voltage Vout which is output from the secondary side of the transformer 73. The converter 10B converts the input voltage Vin based on the primary side ground into the output voltage Vout based on the secondary side ground by the switching of the switching element 72 which is connected to the primary side coil of the transformer 73. The output voltage Vout is applied to a load 78 via the output capacitor 77.

The microcomputer 60 has a plurality of functional blocks. The plurality of functional blocks includes a controller 20, an activation unit 30, a measurement unit 40, and a notification unit 50.

The controller 20 includes an AD (Analog-to-Digital) converter 21, an error calculation unit 22, a compensator 23, and a PWM (Pulse Width Modulation) controller 24.

The AD converter 21 converts a detected value of the output voltage Vout from an analog value into a digital value. The error calculation unit 22 calculates an error between a target value (target voltage) of the output voltage Vout set by the activation unit 30 and the detected value of the output voltage Vout. The compensator 23 calculates a duty ratio D of the converter 10B such that the error becomes zero. The duty ratio D represents a switching duty ratio of the switching element 72 in the converter 10B. The PWM controller 24 switches the switching element 72 so that the switching element 72 switches with the duty ratio D.

The activation unit 30 includes an activation timer 31, a first target voltage setting unit 32, a second target voltage setting unit 33, and a switch 34. The activation timer 31 is activated at a predetermined timing, and outputs an instruction S to cause the output voltage Vout to transit to a transient state. When the activation timer 31 is started to output the instruction S, the switch 34 changes the target value of the output voltage Vout from a target value of the output voltage Vout set by the first target voltage setting unit 32 (target voltage 1) to a target value set by the second target voltage setting unit 32 (target voltage 2). The changed target value is input to the error calculation unit 22. As a result, the compensator 23 calculates the duty ratio D of the converter 10B so that the error between the changed target value and the detected value of the output voltage Vout becomes zero, and the controller 24 switches the switching element 72 with the duty ratio D.

The measurement unit 40 includes a measurement timer 41 and a measurement counter 42 in order to measure the time Ts until the output voltage Vout reaches the predetermined threshold voltage Vt, based on the instruction S. When the activation timer 31 is started to output the instruction S, the measurement timer 41 starts outputting a pulse signal of a constant cycle. The measurement counter 42 counts the pulse signal of a constant cycle output from the measurement timer 41. A numerical value counted by the measurement counter 42 until the output voltage Vout reaches the predetermined threshold voltage Vt based on the instruction S from the activation unit 30 (count value Cn) is a value corresponding to the time Ts. Therefore, the measurement unit 40 may measure the time Ts by causing the measurement counter 42 to count the pulse signal of a constant cycle output from the measurement timer 41 until the output voltage Vout reaches the predetermined threshold voltage Vt based on the instruction S from the activation unit 30. The threshold voltage Vt is stored in advance, for example, in a data table in the memory 61.

After the measurement of the time Ts by the measurement unit 40 is ended, the activation timer 31 is reset and the output of the instruction S is stopped. When the output of the instruction S is stopped, the switch 34 changes the target value of the output voltage Vout from the target value set by the second target voltage setting unit 33 to the target value set by the first target voltage setting unit 32. That is, the target value of the output voltage Vout is returned to the original value and is input to the error calculation unit 22. The subsequent operations of the controller 20 are similar to those described above.

The notification unit 50 includes a deterioration determiner 51 and an alarm unit 52. When it is detected that the above-described count value Cn counted by the measurement counter 42 reaches a predetermined count threshold Tc, the deterioration determiner 51 determines that the converter 10B (in particular, the output capacitor 77) is in a deteriorated state. The alarm unit 52 notifies warning information indicating that the converter 10B or the output capacitor 77 is in a deteriorated state, to an alarm device outside the power supply circuit 101 via an interface such as a power management bus (PMBUS) or the like. The alarm device informs the user of such warning information by display or light emission. By recognizing the warning information from the alarm device, the user may replace the output capacitor 77, the converter 10B, or the power supply circuit 101 before the converter 10B breaks down. It is also possible to replace the device 1 itself that is provided with the power supply circuit 101.

The microcomputer 60 may include an AD converter that converts a detected value of at least one of the input voltage Vin of the converter 10B, the input current Iin of the converter 10B, and the output current Iout of the converter 10B, into a digital value.

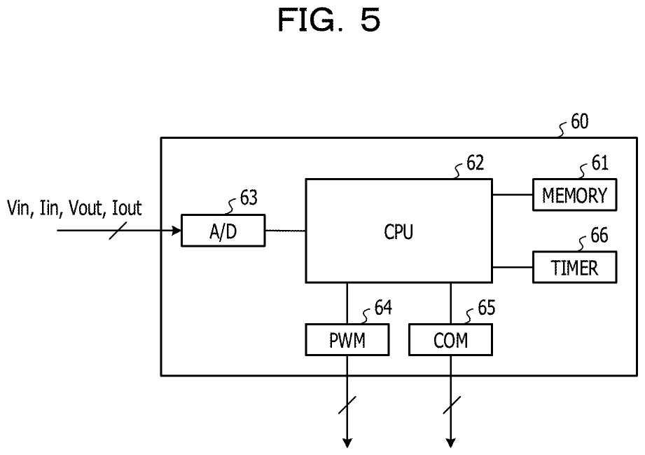

FIG. 5 is a view illustrating an example of the configuration of a microcomputer. The microcomputer 60 includes a memory 61, a central processing unit (CPU) 62, an AD converter 63, a PWM module 64, a communication unit 65, and a timer 66. The functions of the controller 20, the activation unit 30, the measurement unit 40, and the notification unit 50 are implemented when the CPU 62 is operated by a program that is readably stored in the memory 61.

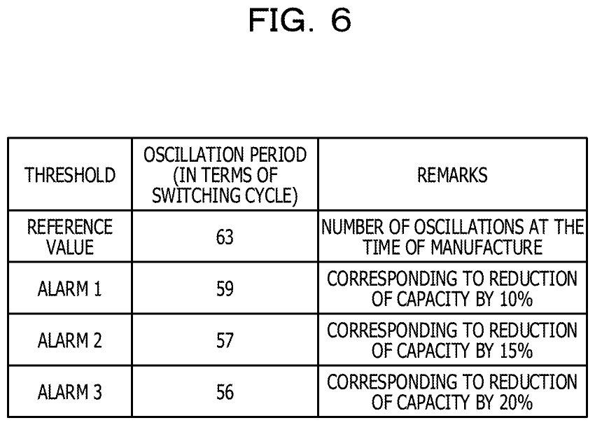

FIG. 6 is a view illustrating a first example of a data table stored in the memory 61, and illustrates a case of measuring the oscillation period of the output voltage Vout. Here, a case where the time Ts measured by the measurement unit 40 is set to the LC resonance period τ_{LC} will be described with reference to FIG. 6. It is assumed that the switching frequency fₛ of the switching element 72 is 100 kHz, the inductance L of the reactor 76 is 10 μH, and the capacitance C of the output capacitor 77 is 1 mF. At this time, the initial value of the LC resonance period τ_{LC} (=2π×√/(L×C)) before the output capacitor 77 is deteriorated is approximately 628 microseconds (μ5). The 628 μs corresponds to a 62.8 (≈63) cycle in terms of switching cycle Tp (=1/fₛ=10 μs). The LC resonance period τ_{LC} becomes shorter as the deterioration of the output capacitor 77 progresses and the capacitance C thereof decreases. Here, the threshold voltage Vt set for measurement of the LC resonance period τ_{LC} is set as a “threshold voltage Vt1”.

Therefore, when the count value Cn counted by the measurement counter 42 reaches a threshold 56 for alarm 3 until the output voltage Vout reaches the threshold voltage Vt1, the deterioration determiner 51 determines that the output capacitor 77 is in a deteriorated state where the capacity is reduced by 20%. Then, the alarm unit 52 outputs the alarm 3 indicating that the capacity has been reduced by 20%, as the warning information.

When the count value Cn counted by the measurement counter 42 reaches a threshold 57 for alarm 2 until the output voltage Vout reaches the threshold voltage Vt1, the deterioration determiner 51 determines that the output capacitor 77 is in a deteriorated state where the capacity is reduced by 15%. Then, the alarm unit 52 outputs the alarm 2 indicating that the capacity has been reduced by 15%, as the warning information.

When the count value Cn counted by the measurement counter 42 reaches a threshold 59 for alarm 1 until the output voltage Vout reaches the threshold voltage Vt1, the deterioration determiner 51 determines that the output capacitor 77 is in a deteriorated state where the capacity is reduced by 10%. Then, the alarm unit 52 outputs the alarm 1 indicating that the capacity has been reduced by 10%, as the warning information.

When the count value Cn counted by the measurement counter 42 reaches a reference threshold 63 until the output voltage Vout reaches the threshold voltage Vt1, the deterioration determiner 51 determines that the output capacitor 77 is in a non-deteriorated state. In this case, the alarm unit 52 does not output warning information. The reference threshold 63 is a converted value corresponding to the initial value of the LC resonance period τ_{LC} before deterioration.

Thus, the notification unit 50 may notify a warning when the time Ts measured by the measurement unit 40 is shorter than the predetermined reference threshold.

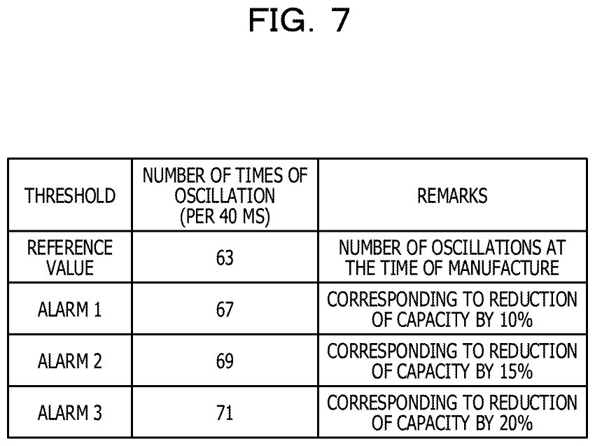

FIG. 7 is a view illustrating a second example of the data table stored in the memory 61, and illustrates a case of measuring the number of oscillations of the output voltage Vout. Here, with reference to FIG. 7, descriptions will be made on a case where the time Ts measured by the measurement unit 40 is set to a predetermined unit period P. It is assumed that the switching frequency fₛ of the switching element 72 is 100 kHz, the inductance L of the reactor 76 is 10 μH, and the capacitance C of the output capacitor 77 is 1 mF. At this time, the initial value of the LC resonance period τ_{LC}(=2π×√(L×C)) before the output capacitor 77 is deteriorated is approximately 628 microseconds (μS). The 628 μs corresponds to 48 oscillations per 40 ms when the unit period P is 40 milliseconds (ms). The number of oscillations per unit period increases as the deterioration of the output capacitor 77 progresses and its capacitance C decreases.

Therefore, when the count value Cm counted by the measurement counter 42 based on the instruction S reaches a reference threshold 63 until the measurement time measured by the measurement timer 41 matches at 40 ms, the deterioration determiner 51 determines that the output capacitor 77 is in a non-deteriorated state. In this case, the alarm unit 52 does not output warning information. The reference threshold 63 is a converted value corresponding to the initial value of the number of vibrations per unit period P.

When the count value Cm counted by the measurement counter 42 based on the instruction S reaches a threshold 67 for alarm 1 until the measurement time measured by the measurement timer 41 matches at 40 ms, the deterioration determiner 51 determines that the output capacitor 77 is in a deteriorated state where the capacity is reduced by 10%. Then, the alarm unit 52 outputs the alarm 1 indicating that the capacity has been reduced by 10%, as the warning information.

When the count value Cm counted by the measurement counter 42 based on the instruction S reaches a threshold 69 for alarm 2 until the measurement time measured by the measurement timer 41 matches at 40 ms, the deterioration determiner 51 determines that the output capacitor 77 is in a deteriorated state where the capacity is reduced by 15%. Then, the alarm unit 52 outputs the alarm 2 indicating that the capacity has been reduced by 15%, as the warning information.

When the count value Cm counted by the measurement counter 42 based on the instruction S reaches a threshold 71 for alarm 3 until the measurement time measured by the measurement timer 41 matches at 40 ms, the deterioration determiner 51 determines that the output capacitor 77 is in a deteriorated state where the capacity is reduced by 20%. Then, the alarm unit 52 outputs the alarm 3 indicating that the capacity has been reduced by 20%, as the warning information.

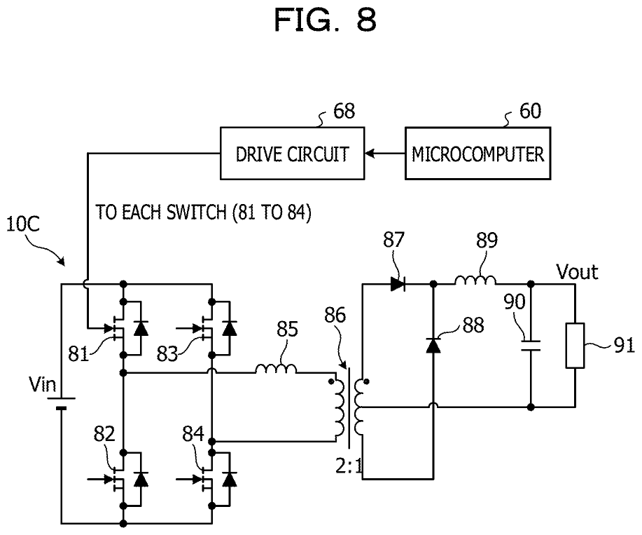

FIG. 8 is a view illustrating another example of the configuration of the voltage conversion unit 10. A full bridge converter 10C is an example of the converter 10. The full bridge converter 10C includes switching elements 81 to 84, a reactor 85, a transformer 86, diodes 87 and 88, a reactor 89, and an output capacitor 90. The output voltage Vout of the full bridge converter 10C is smoothed by the output capacitor 90 and supplied to a load 91.

The configuration of the microcomputer 60 is similar to that described above. The PWM controller 24 in the microcomputer 60 switches the switching elements 81 to 84 ON or OFF via a drive circuit 68.

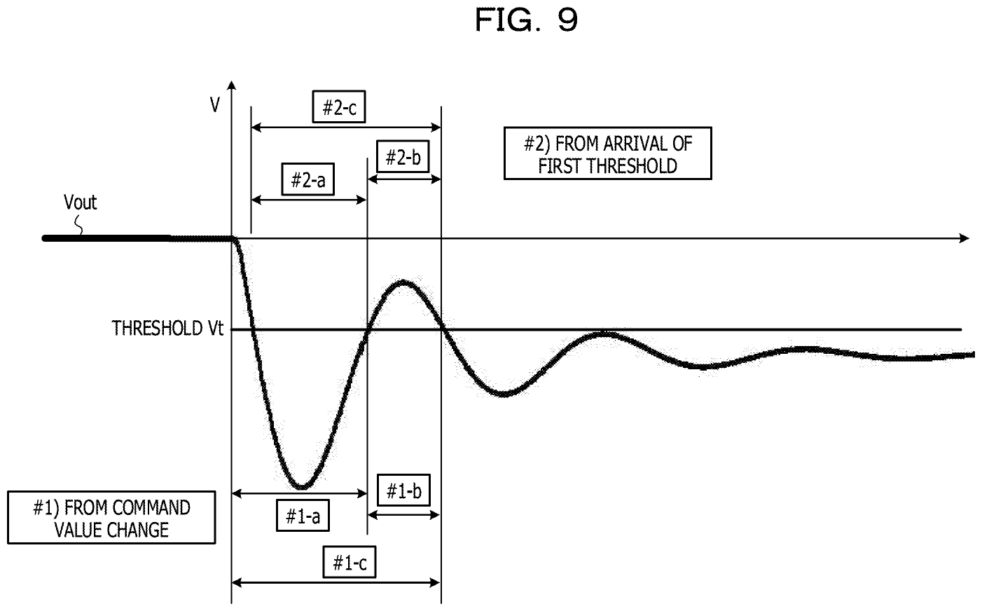

FIG. 9 is a view illustrating a first example #1 and a second example #2 of an aging deterioration detection method in which the vertical axis represents a voltage V and the horizontal axis represents time t. At a certain timing in a stable state in which the output voltage Vout is maintained at a constant target value by the controller 20, the activation unit 30 outputs an instruction S to change the target value of the output voltage Vout. In the first example #1 and the second example #2, the measurement unit 40 measures the time Ts until the output voltage Vout reaches the threshold voltage Vt after the output voltage Vout crosses the threshold voltage Vt a predetermined number of times (two times in FIG. 9). The predetermined number of times is not limited to two, but may be appropriately set to one or three or more.

In the first example #1, the measurement unit 40 starts measurement of the time Ts starting from “when a command value is changed” at which the instruction S is output, and uses the measurement counter 42 to measure the time of an interval “#1−c” as the time Ts. The time of the interval “#1−c” is the sum of the time of an interval “#1−a” and the time of an interval “#1−b”.

In the meantime, in the second example #2, the measurement unit 40 starts measurement of the time Ts starting from the time when the output voltage Vout after the output of the instruction S crosses the threshold voltage Vt for the first time, and uses the measurement counter 42 to measure the time of an interval “#2−c” as the time Ts. The time of the interval “#2−c” is the sum of the time of an interval “#2−a” and the time of an interval “#2−b”.

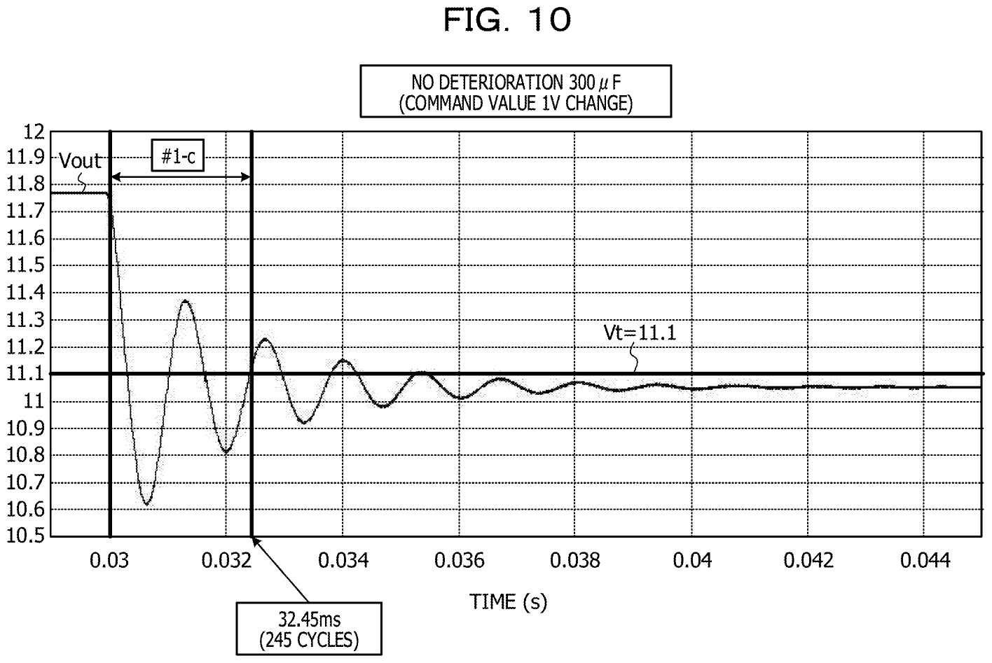

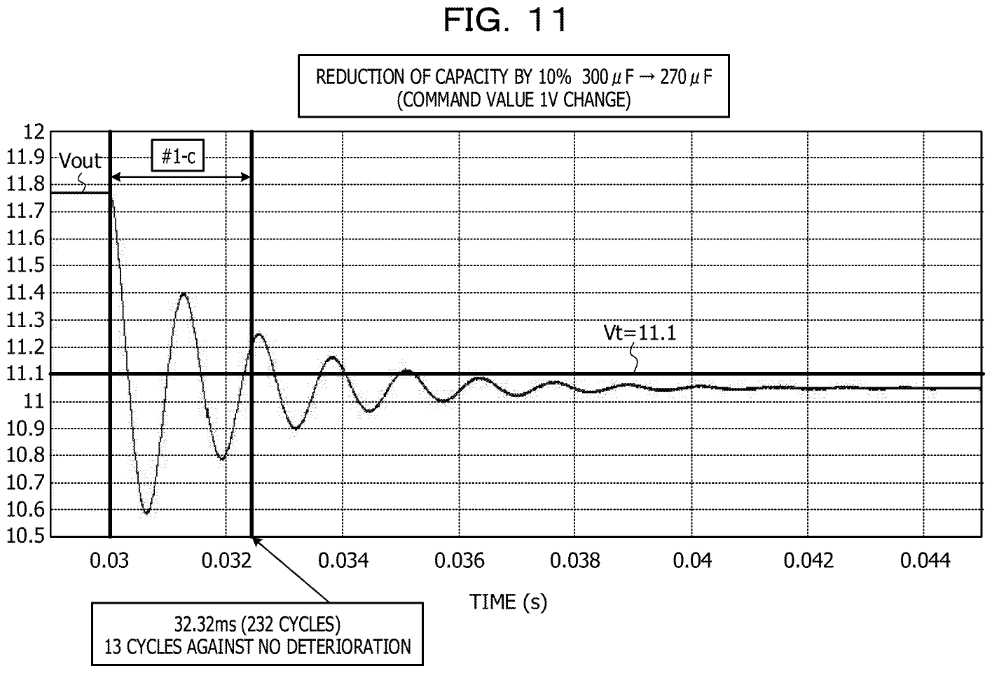

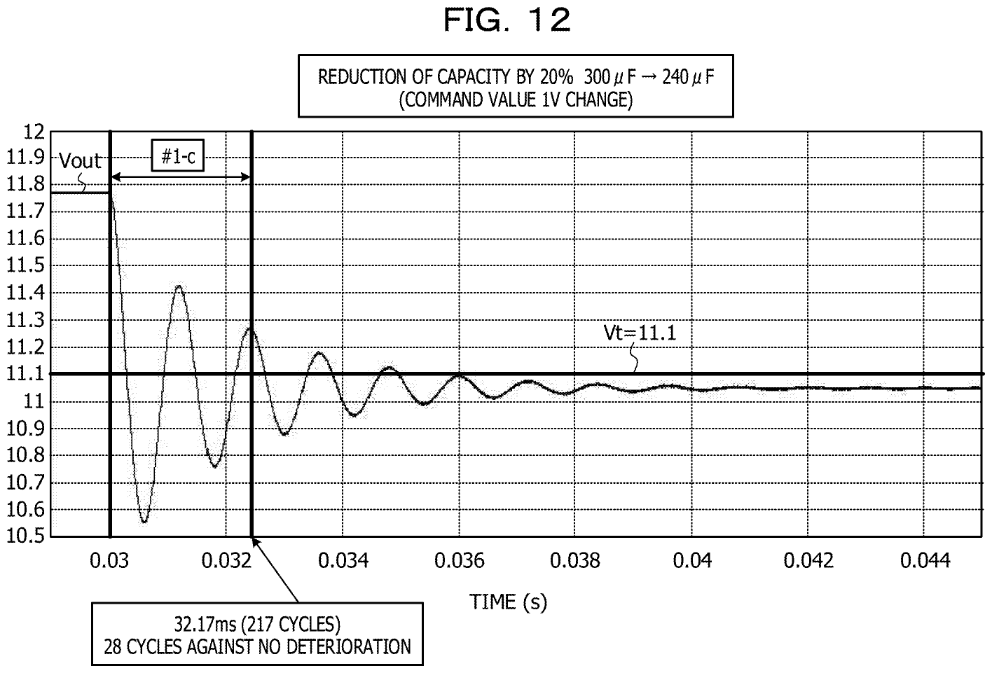

FIGS. 10 to 12 illustrate examples of waveforms in a transient state of the output voltage Vout when the target value of the output voltage Vout is decreased by 1 volt. When the output capacitor is not deteriorated, when the capacity is reduced by 10%, and when the capacity is reduced by 20%, the count value Cn is 245 cycles, 232 cycles, and 217 cycles in terms of switching cycle Tp, respectively.

Therefore, the deterioration determiner 51 may determine the degree of deterioration of the converter (in particular, the output capacitor) based on a difference in the count value Cn counted by the measurement counter 42 until the output voltage Vout reaches the threshold voltage Vt. For example, the deterioration determiner 51 may determine the degree of deterioration of the output capacitor by detecting the degree of decrease with respect to the reference value (245 cycles) of the switching cycle corresponding to the time Ts.

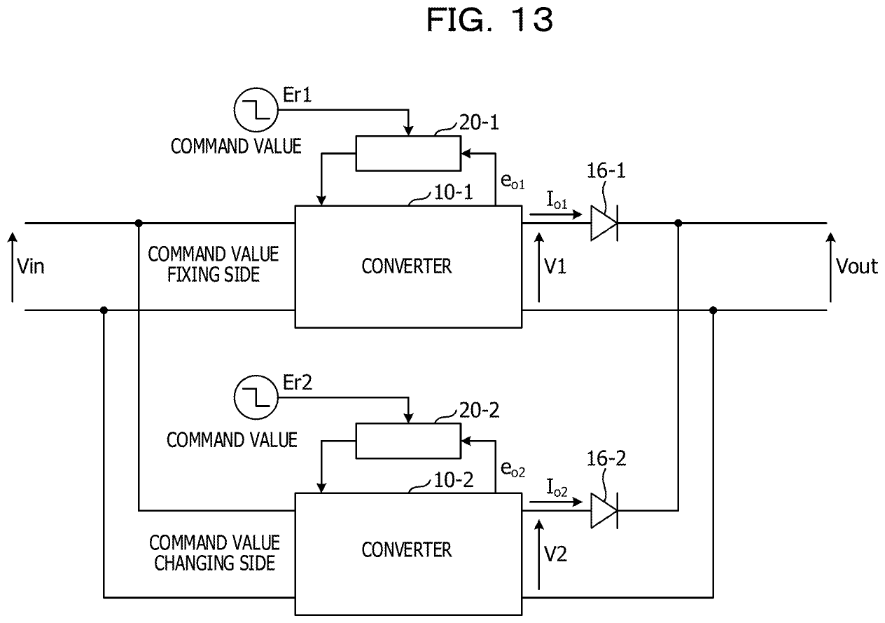

FIG. 13 is a view illustrating another example of the configuration of the power supply circuit. Converters 10-1 and 10-2 are examples of the converter 10 and have the same circuit configuration. The converter 10-1 converts an input voltage Vin into an output voltage V1 and supplies an output current Iₒ₁ to a load via a diode 16-1. The converter 10-2 converts the input voltage Vin to an output voltage V2 and supplies an output current Iₒ₂ to the load via a diode 16-2. By connecting the converters 10-1 and 10-2 in parallel, for example, even when one of the converters fails, the other converter may continue to operate.

Controllers 20-1 and 20-2 are examples of the controller 20 and have the same circuit configuration. The controller 20-1 controls the voltage conversion of the converter 10-1 such that an error between a target value Er1 of the output voltage V1 and a detected value eₒ₁ of the output voltage V1 becomes zero. The controller 20-2 controls the voltage conversion of the converter 10-2 such that an error between a target value Er2 of the output voltage V2 and a detected value eₒ₂ of the output voltage V2 becomes zero. The target value Er1 is a fixed command value, and the target value Er2 is a variable command value.

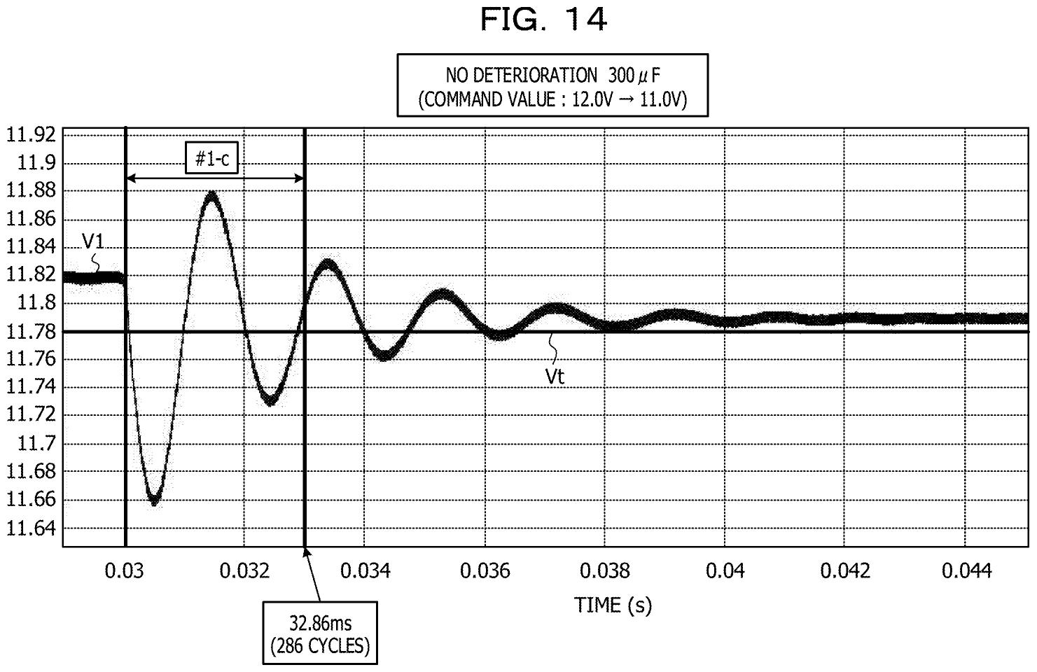

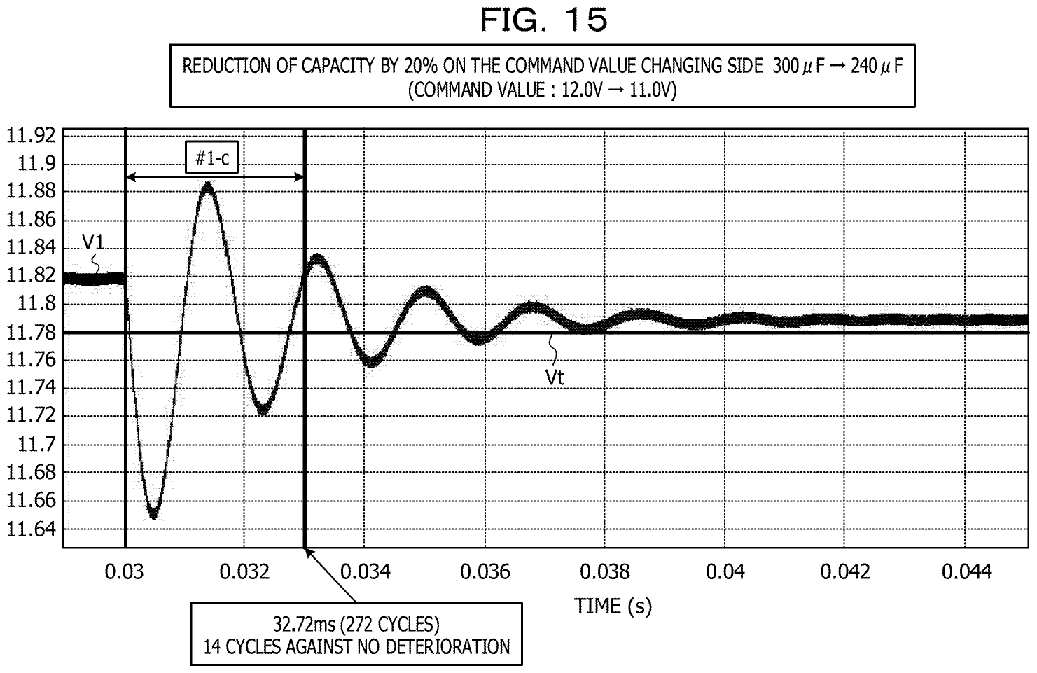

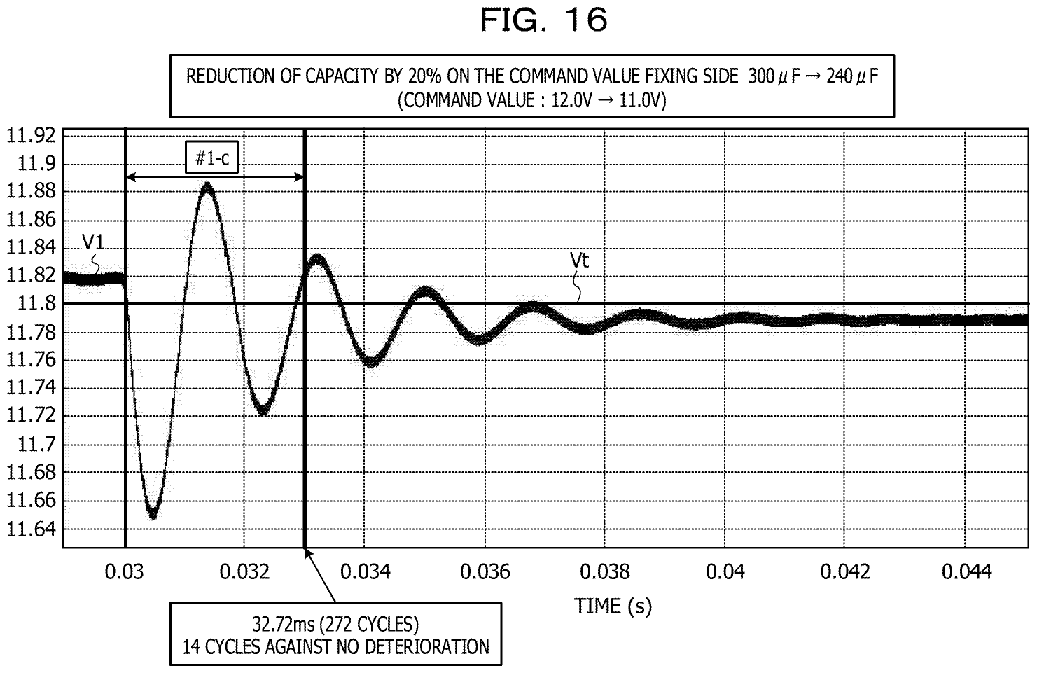

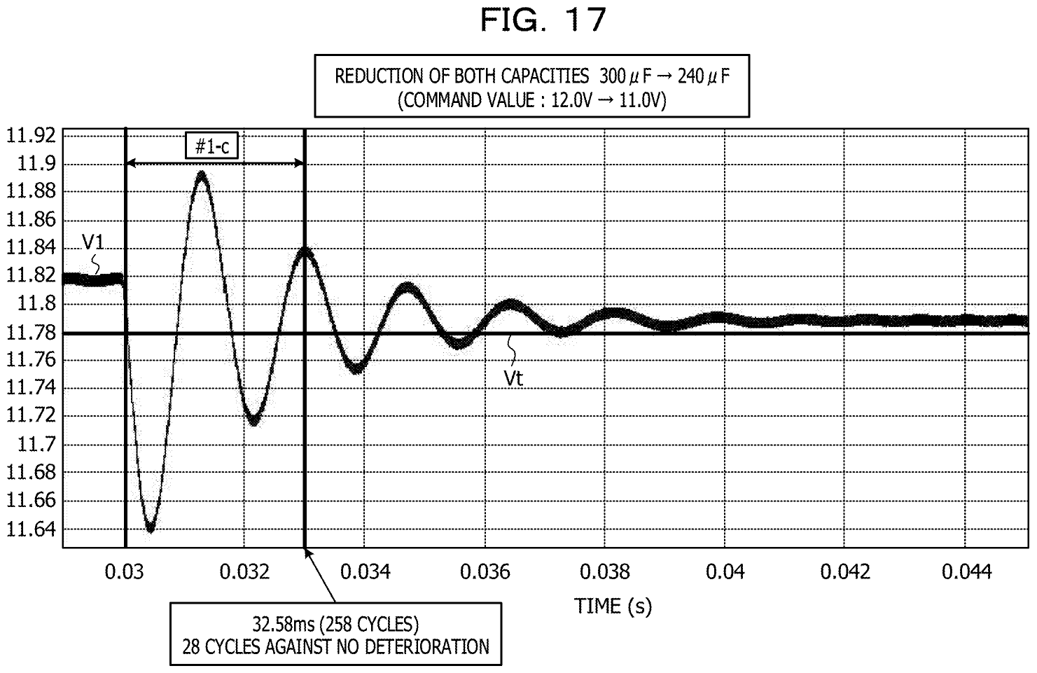

FIGS. 14 to 17 illustrate examples of waveforms in a transient state of the output voltage V1 when the target value Er2 of the output voltage V2 is decreased by 1 volt. FIG. 14 illustrates a case where the output capacitors of the converter 10-1 on the command value fixing side and the converter 10-2 on the command value changing side are not deteriorated. FIG. 15 illustrates a case where the capacitance of the output capacitor on the command value changing side has reduced by 20%. FIG. 16 illustrates a case where the capacitance of the output capacitor on the command value fixing side has reduced by 20%. FIG. 17 illustrates a case where the capacitance of the output capacitors on the command value changing side and the command value fixing side has reduced by 20%. In FIGS. 14 to 17, the count value Cn is 286 cycles, 272 cycles, 272 cycles, and 258 cycles in terms of switching cycle Tp, respectively.

Therefore, the deterioration determiner 51 may determine the degree of deterioration of each converter (in particular, each output capacitor) in parallel operation based on a difference in count value Cn counted by the measurement counter 42 until the output voltage Vout reaches the threshold voltage Vt. In addition, when the capacitance of the output capacitor on the command value fixing side decreases (FIG. 16), the switching cycle corresponding to the time Ts decreases in the same way as when the capacitance of the output capacitor on the command value changing side decreases (FIG. 15). Therefore, even when only the command value of one of the converters is changed, the deterioration determiner 51 may determine that one of the output capacitors is deteriorated.

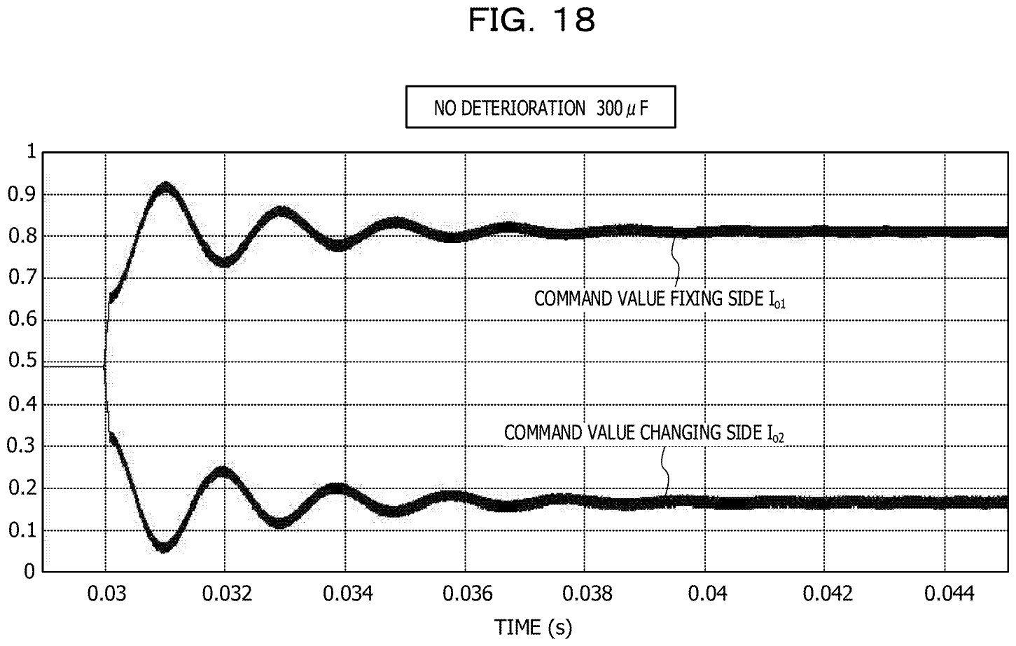

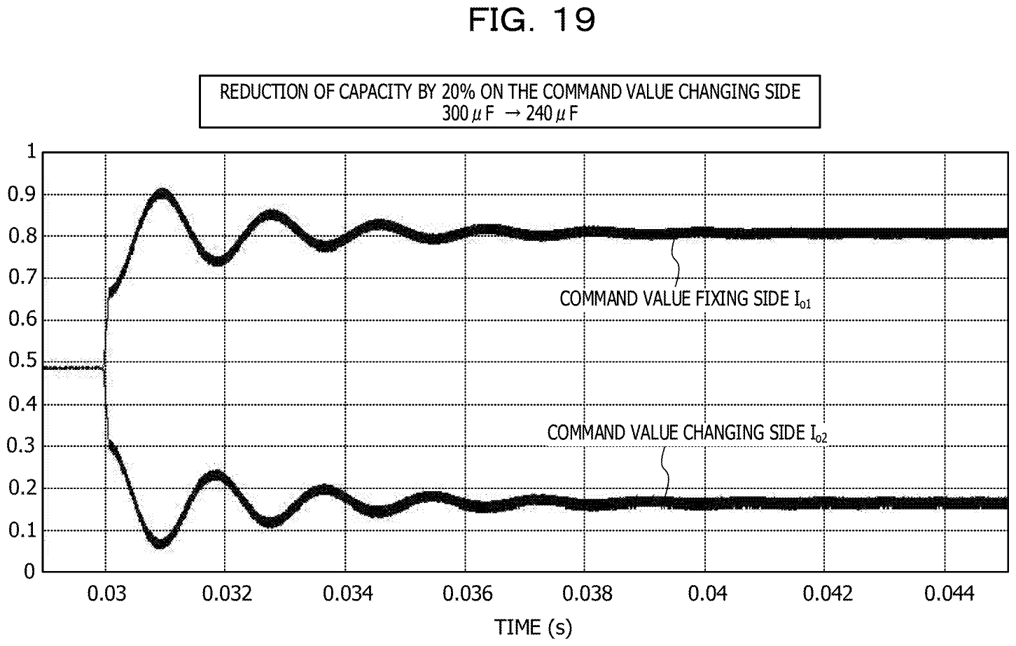

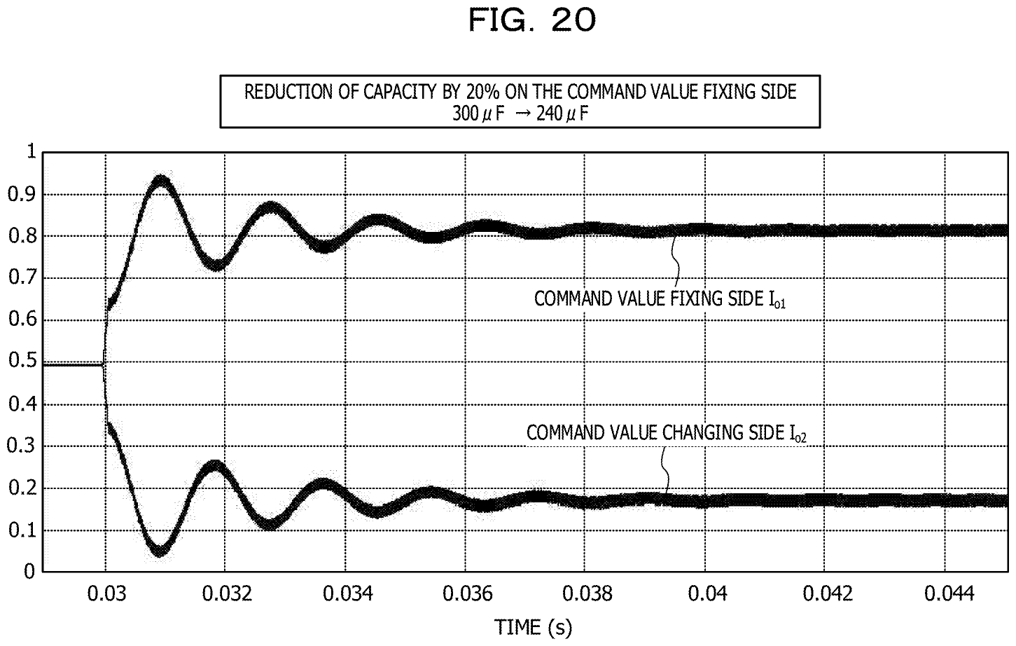

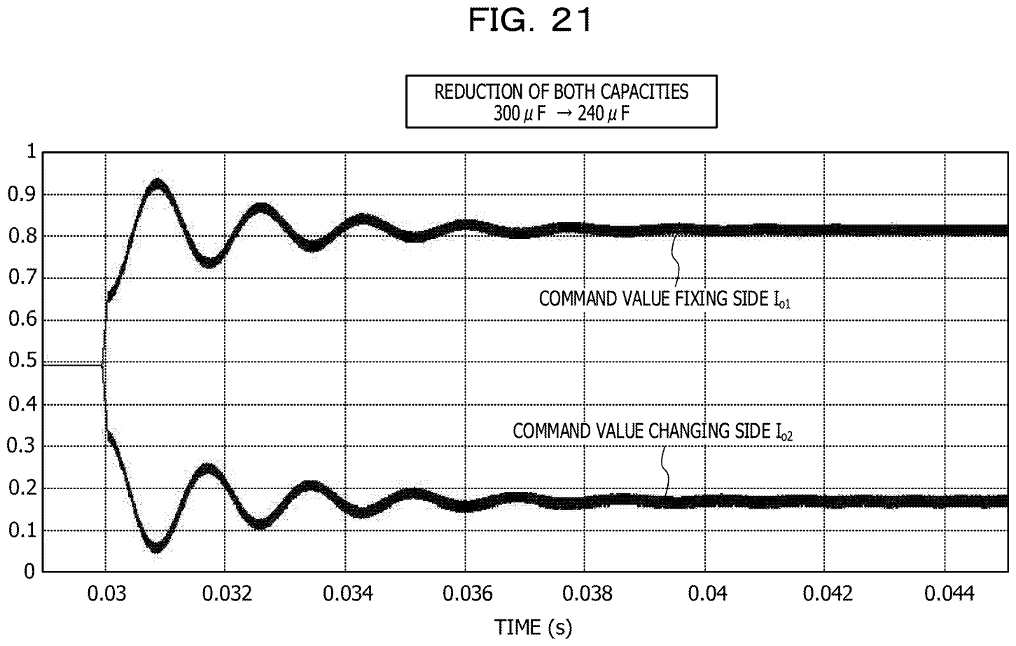

FIGS. 18 to 21 illustrate examples of waveforms of the output currents Iₒ₁ and Iₒ₂ in a transient state when the target value Erg of the output voltage V2 is decreased by 1 volt. FIG. 18 illustrates a case where the output capacitors of the converter 10-1 on the command value fixing side and the converter 10-2 on the command value changing side are not deteriorated. FIG. 19 illustrates a case where the capacitance of the output capacitor on the command value changing side has reduced by 20%. FIG. 20 illustrates a case where the capacitance of the output capacitor on the command value fixing side has reduced by 20%. FIG. 21 illustrates a case where the capacitance of the output capacitors on the command value changing side and the command value fixing side has reduced by 20%.

The envelope of a current waveform is different between the case where the capacitance of the output capacitor on the command value changing side has reduced by 20% (FIG. 19) and the case where the capacitance of the output capacitor on the command value fixing side has reduced by 20% (FIG. 20). Therefore, the deterioration determiner 51 may specify which converter output capacitor has deteriorated, based on the difference in the envelopes of the current waveforms of the output currents Iₒ₁ and Iₒ₂.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to an illustrating of the superiority and inferiority of the invention. Although the embodiments of the present invention have been described in detail, it should be understood that the various changes, substitutions, and alterations could be made hereto without departing from the spirit and scope of the invention.

What is claimed is:

1. A power supply circuit comprising:
a converter configured to convert an input voltage into an output voltage;
a memory; and
a processor coupled to the memory and the processor configured to:
control the converter so as to make the output voltage constant;
control the converter so as to cause the output voltage to transit to a transient state, based on an instruction;
measure a first time until the output voltage reaches a first voltage, based on the instruction; and
generate a warning signal when the first time reaches a second time.

2. The power supply circuit according to claim 1,
wherein the first time is a time from when the output voltage crosses the first voltage a predetermined number of times to when the output voltage continually approaches the first voltage.

3. The power supply circuit according to claim 2,
wherein the predetermined number of times is two.

4. The power supply circuit according to claim 1,
wherein the converter is configured to include an output capacitor to smooth the output voltage, and
wherein the processor is configured to generate the warning signal when the first time is shorter than the second time.

5. The power supply circuit according to claim 1,
wherein the processor is configured to control the converter so as to change a target value of the output voltage by a predetermined voltage change amount, based on the instruction.

6. The power supply circuit according to claim 1,
wherein the converter is configured to have a CR time constant larger than an LC resonance period of the converter.

7. The power supply circuit according to claim 1,
wherein the processor is configured to measure the first time starting from the instruction.

8. The power supply circuit according to claim 1,
wherein the processor is configured to measure the first time from a time when the output voltage crosses the first voltage once.

9. A power supply circuit comprising:
a converter configured to convert an input voltage into an output voltage;
a memory; and
a processor coupled to the memory and the processor configured to:
control the convert so as to make the output voltage constant;
control the converter so as to cause the output voltage to transit to a transient state, based on an instruction;
measure a number of oscillations of the output voltage in a predetermined period; and
generate a warning signal when the measured number of oscillations reaches a predetermined number.
